(19) United States
(12) Patent Application Publication
(10) Pub. No.: US 2026/0068247 A1
(43) Pub. Date: Mar. 5, 2026

(54) SUPERJUNCTION SEMICONDUCTOR DEVICE

(71) Applicant: FUJI ELECTRIC CO., LTD., Kawasaki-shi (JP)

(72) Inventor: Noriaki YAO, Matsumoto-city (JP)

(73) Assignee: FUJI ELECTRIC CO., LTD., Kawasaki-shi (JP)

(21) Appl. No.: 19/251,499

(22) Filed: Jun. 26, 2025

(30) Foreign Application Priority Data
Aug. 27, 2024 (JP) 2024-146050

(51) Int. Cl. H10D 62/10; H10D 30/66; H10D 62/60; H10D 64/00

(52) U.S. Cl. CPC H10D 62/126; H10D 30/665; H10D 62/111; H10D 62/60; H10D 64/112

(57) ABSTRACT

A semiconductor device, having: a semiconductor substrate; a first semiconductor layer provided on the semiconductor substrate; a second semiconductor layer provided on the first semiconductor layer; and a parallel pn region provided in the second semiconductor layer. The parallel pn region includes a plurality of first column regions and a plurality of second column regions disposed in parallel and repeatedly alternating with each other in a first direction parallel to a surface of the second semiconductor layer. In a termination structure region of the semiconductor device, the depths of the first and second column regions decrease stepwise in the first direction, to form a plurality of height steps. In a sectional view parallel to the second semiconductor layer, the parallel pn region is surrounded by a semiconductor region of an annular shape, which is connected to the first or second column regions of a same conductivity type.

### CROSS REFERENCE TO RELATED APPLICATIONS

This application is based upon and claims the benefit of priority of the prior Japanese Patent Application No. 2024-146050, filed on Aug. 27, 2024, the entire contents of which are incorporated herein by reference.

### BACKGROUND OF THE INVENTION

### 1. Field of the Invention

Embodiments of the present disclosure relate to a superjunction semiconductor device.

### 2. Description of the Related Art

Conventionally, a technique has been disclosed in which in a superjunction semiconductor device, the closer an n-type column region and a p-type column region of a parallel pn region are to an end of the superjunction semiconductor device, the shallower is a depth thereof from the surface of said n-type column region and said p-type column region (for example, refer to Japanese Laid-Open Patent Publication No. 2023-135674). Further, a technique has been disclosed in which in a parallel pn region of a termination region, in a portion of the region, a top portion p-type layer ring and a center portion p-type layer ring are provided (for example, refer to Japanese Laid-Open Patent Publication No. 2019-021788). Further, a technique has been disclosed in which in an edge termination region, n-type columns and p-type columns are provided in annular shapes so as to surround an active region (for example, refer to Japanese Laid-Open Patent Publication No. 2023-132670).

### SUMMARY OF THE INVENTION

A semiconductor device having an active region through which a current flows, and a termination structure region surrounding a periphery of the active region in a plan view of the semiconductor device, the semiconductor device includes: a semiconductor substrate of a first conductivity type; a first semiconductor layer of the first conductivity type, provided at a surface of the semiconductor substrate, the first semiconductor layer having a dopant concentration lower than a dopant concentration of the semiconductor substrate; a second semiconductor layer of the first conductivity type, provided at a surface of the first semiconductor layer, the second semiconductor layer having a dopant concentration lower than the dopant concentration of the first semiconductor layer; and a parallel pn region provided in the second semiconductor layer, the parallel pn region including a plurality of first column regions of the first conductivity type and a plurality of second column regions of a second conductivity type that are disposed in parallel and repeatedly alternating with each other in a first direction parallel to the surface of the second semiconductor layer, each of the plurality of first and second column regions extending to a depth in a depth direction perpendicular to the first direction. In the termination structure region, the depths of the plurality of first and second column regions decrease stepwise in the first direction, to form a plurality of height steps from an inner side of the parallel pn region to an outer side thereof. In a sectional view of the semiconductor device parallel to the surface of the second semiconductor layer, the parallel pn region is surrounded by a semiconductor region of an annular shape, which has a constant distance from the active region and is connected to either the first column regions or the second column regions that are of a same conductivity type as the semiconductor region.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a top view a SJ-MOSFET according to an embodiment.

FIG. 2 is a cross-sectional view depicting a first structure of the SJ-MOSFET according to the embodiment, along cutting line A-A′.

FIG. 3 is a cross-sectional view depicting the first structure of the SJ-MOSFET according to the embodiment, along cutting line B-B′.

FIG. 4 is a cross-sectional view depicting the first structure of the SJ-MOSFET according to the embodiment, along cutting line C-C′.

FIG. 5 is a plan view depicting the first structure of the SJ-MOSFET according to the embodiment, along cutting line D-D′.

FIG. 6 is a plan view depicting the first structure of the SJ-MOSFET according to the embodiment, along cutting line E-E′.

FIG. 7 is a plan view depicting the first structure of the SJ-MOSFET according to the embodiment, along cutting line F-F′.

FIG. 8 is a plan view depicting a conceptual image of paths of hole carriers remaining in a termination region during a reverse recovery process of the conventional SJ-MOSFET, at a depth indicated by cutting line E-E′ in cross-sectional views depicted in FIGS. 34 to 36.

FIG. 9 is a plan view depicting a conceptual image of paths of hole carriers remaining in a termination region during a reverse recovery process in the SJ-MOSFET according to the embodiment, at a depth indicated by cutting line E-E′ in the cross-sectional views depicted in FIGS. 2 to 4.

FIG. 10 is a cross-sectional view depicting a second structure of the SJ-MOSFET according to the embodiment, along cutting line A-A′.

FIG. 11 is a cross-sectional view depicting the second structure of the SJ-MOSFET according to the embodiment, along cutting line B-B′.

FIG. 12 is a cross-sectional view depicting the second structure of the SJ-MOSFET according to the embodiment, along cutting line C-C′.

FIG. 13 is a plan view depicting the second structure at a depth indicated by cutting line G-G′ depicted in the cross-sectional views of the second structure in FIGS. 10 to 12.

FIG. 14 is a cross-sectional view depicting a third structure of the SJ-MOSFET according to the embodiment, along cutting line A-A′.

FIG. 15 is a cross-sectional view depicting the third structure of the SJ-MOSFET according to the embodiment, along cutting line B-B′.

FIG. 16 is a cross-sectional view depicting the third structure of the SJ-MOSFET according to the embodiment, along cutting line C-C′.

FIG. 17 is a cross-sectional view depicting a fourth structure of the SJ-MOSFET according to the embodiment, along cutting line A-A′.

FIG. 18 is a cross-sectional view depicting the fourth structure of the SJ-MOSFET according to the embodiment, along cutting line B-B′.

FIG. 19 is a cross-sectional view depicting the fourth structure of the SJ-MOSFET according to the embodiment, along cutting line C-C′.

FIG. 20 is a cross-sectional view depicting the fourth structure of the SJ-MOSFET according to the embodiment, along cutting line H-H′.

FIG. 21 is a cross-sectional view depicting the fourth structure of the SJ-MOSFET according to the embodiment, along cutting line I-I′.

FIG. 22 is a cross-sectional view depicting a fifth structure of the SJ-MOSFET according to the embodiment, along cutting line A-A′.

FIG. 23 is a cross-sectional view depicting the fifth structure of the SJ-MOSFET according to the embodiment, along cutting line B-B′.

FIG. 24 is a cross-sectional view depicting the fifth structure of the SJ-MOSFET according to the embodiment, along cutting line C-C′.

FIG. 25 is a cross-sectional view depicting a sixth structure of the SJ-MOSFET according to the embodiment, along cutting line A-A′.

FIG. 26 is a cross-sectional view depicting the sixth structure of the SJ-MOSFET according to the embodiment, along cutting line B-B′.

FIG. 27 is a cross-sectional view depicting the sixth structure of the SJ-MOSFET according to the embodiment, along cutting line C-C′.

FIG. 28 is a cross-sectional view depicting a seventh structure of the SJ-MOSFET according to the embodiment, along cutting line A-A′.

FIG. 29 is a cross-sectional view depicting the seventh structure of the SJ-MOSFET according to the embodiment, along cutting line B-B′.

FIG. 30 is a cross-sectional view depicting the seventh structure of the SJ-MOSFET according to the embodiment, along cutting line C-C.

FIG. 31 is a plan view of a structure of a conventional SJ-MOSFET at a depth indicated by cutting line D-D′.

FIG. 32 is a plan view of the structure of the conventional SJ-MOSFET at a depth indicated by cutting line E-E′.

FIG. 33 is a plan view of the structure of the conventional SJ-MOSFET at a depth F-F′.

FIG. 34 is a cross-sectional view of the structure of the conventional SJ-MOSFET, along cutting line A-A′.

FIG. 35 is a cross-sectional view of the structure of the conventional SJ-MOSFET, along cutting line B-B′.

FIG. 36 is a cross-sectional view of the structure of the conventional SJ-MOSFET, along cutting line C-C′.

### DETAILED DESCRIPTION OF THE INVENTION

First, problems associated with the conventional techniques are discussed. In a conventional superjunction semiconductor device a problem arises in that, in the termination region, there are two types of structures including a structure parallel to the parallel pn column region and a structure horizontal thereto, in the drift layer. However, the manner in which the depletion layer spreads and the electric field distribution in each type of structure differs between the types of structure, whereby a problem arises in that design is complicated.

Findings underlying the present disclosure are discussed. A superjunction semiconductor device according to the present disclosure achieving an object and solving the problems described has the following features. The superjunction semiconductor device is a semiconductor device having an active region through which a current flows and a termination structure region in which a voltage withstanding structure surrounding a periphery of the active region in a plan view of the semiconductor device is disposed, the termination structure region being disposed outside of the active region. The termination structure region has: a first semiconductor layer of a first conductivity type, provided at a surface of a semiconductor substrate, the first semiconductor layer having a dopant concentration lower than a dopant concentration of the semiconductor substrate; a second semiconductor layer of the first conductivity type, provided at a surface of the first semiconductor layer, the second semiconductor layer having a dopant concentration lower than the dopant concentration of the first semiconductor layer; and a parallel pn region provided in the second semiconductor layer and in which a plurality of first column regions of the first conductivity type and a plurality of second column regions of a second conductivity type are disposed repeatedly alternating with each other in a direction parallel to the surface of the second semiconductor layer. Depths of the plurality of first column regions and the plurality of second column regions decrease stepwise in a direction to ends of the parallel pn region, and a bottom portion or an outermost portion of the parallel pn region, the outermost portion being positioned closest to the ends of the parallel pn region, is formed in an annular shape maintaining a constant distance from the active region and is connected to parallel column regions of a same conductivity type.

According to the disclosure above, a portion of the parallel pn region is connected to parallel columns of a same conductivity type, whereby the manner in which the depletion layer spreads and the electric field distribution of the differing termination structures are made uniform, enabling a difference in the breakdown voltages of the differing structures to be reduced. Furthermore, connection of the parallel columns of the same conductivity type spreads (distributes) current paths for excess carriers discharged during avalanche breakdown and reverse recovery, whereby current may be suppressed from concentrating.

Further, the superjunction semiconductor device according to the present disclosure, in the disclosure above, further includes a first semiconductor region of the first conductivity type, provided outermost in the parallel pn region and connected to the plurality of first column regions that are parallel.

Further, the superjunction semiconductor device according to the present disclosure, in the disclosure above, further includes a second semiconductor region of the second conductivity type, provided in the bottom portion of the parallel pn region and connected to the plurality of second column regions that are parallel.

Further, in the superjunction semiconductor device according to the present disclosure, in the disclosure above, in each location where the plurality of first column regions becomes shallower stepwise, the second semiconductor region is provided in innermost bottom portions of the plurality of first column regions, closest to the active region.

Further, in the superjunction semiconductor device according to the present disclosure, in the disclosure above, the second semiconductor region is provided in a bottom portion of each of the plurality of second column regions, intervening between an adjacent two of the plurality of first column regions, having a same depth as a depth of the each of the plurality of second column regions.

Further, in the superjunction semiconductor device according to the present disclosure, in the disclosure above, the active region has: the semiconductor substrate; the first semiconductor layer provided at the surface of semiconductor substrate; the second semiconductor layer provided at the surface of the first semiconductor layer; and the parallel pn region provided in the second semiconductor layer, and the depths of the plurality of first column regions and the plurality of second column regions of the termination structure region are shallower than depths of the plurality of first column regions and the plurality of second column regions of the active region.

Further, in the superjunction semiconductor device according to the present disclosure, in the disclosure above, the depths of the plurality of first column regions and the plurality of second column regions decrease stepwise in three or more steps.

Findings underlying the present disclosure are discussed. First, problems associated with the conventional superjunction semiconductor device are discussed. Metal oxide semiconductor field effect transistors (MOSFETs) and insulated gate bipolar transistors (IGBTs) are widely used as power converting semiconductor devices. A superjunction MOSFET (SJ-MOSFET) in which parallel pn column regions are disposed in a drift layer has a smaller on-resistance than a standard MOSFET and thus enables reductions in the size of the device and increased speeds, and is used in various applications.

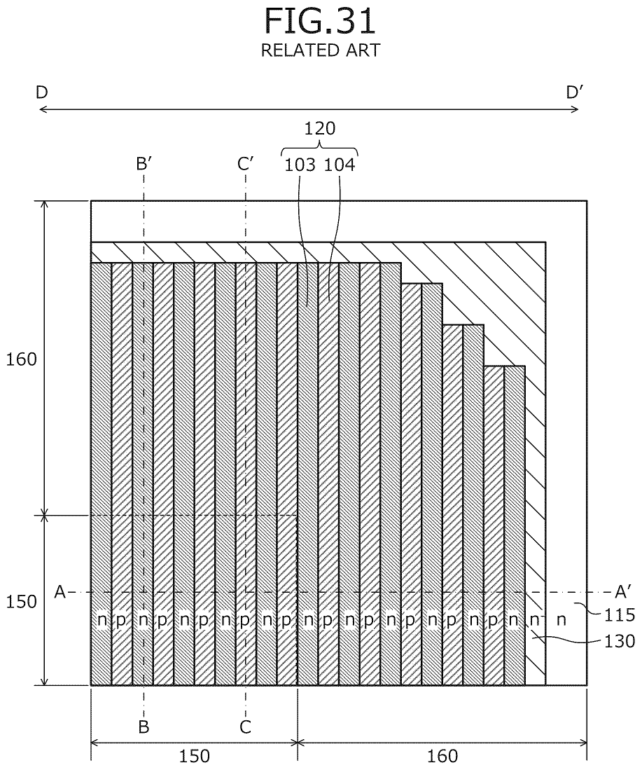

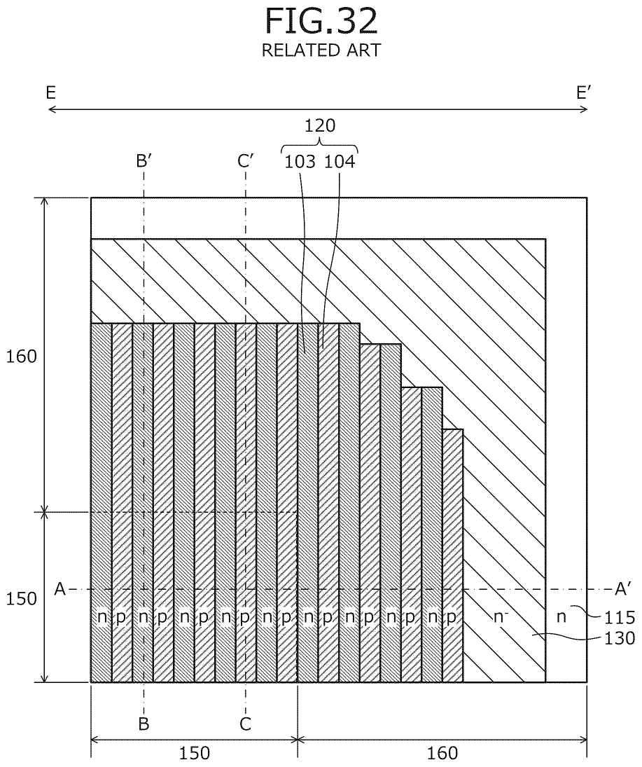

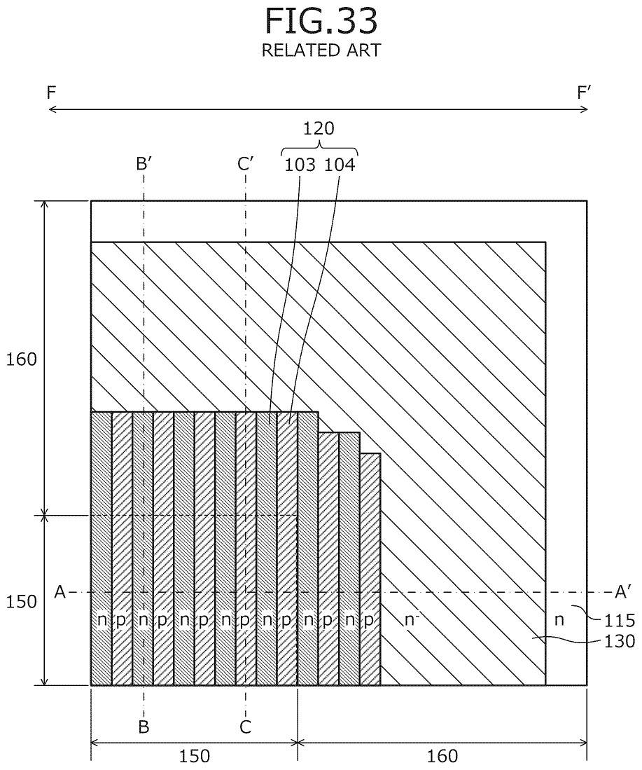

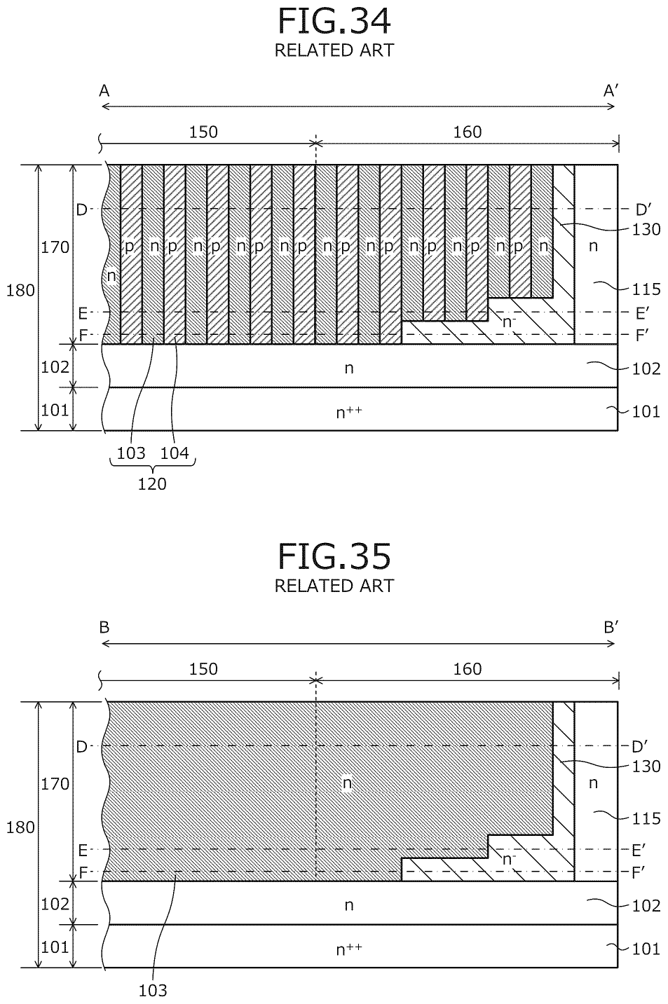

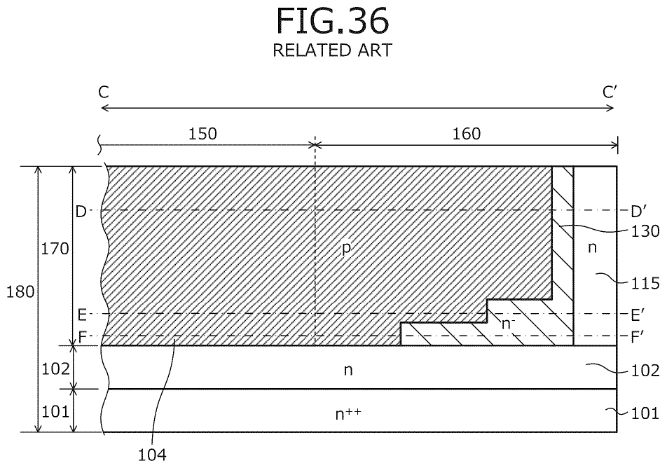

FIG. 31 is a plan view of a structure of a conventional SJ-MOSFET at a depth indicated by cutting line D-D′. FIG. 32 is a plan view of the structure of the conventional SJ-MOSFET at a depth indicated by cutting line E-E′. FIG. 33 is a plan view of the structure of the conventional SJ-MOSFET at a depth F-F′. FIG. 34 is a cross-sectional view of the structure of the conventional SJ-MOSFET, along cutting line A-A′. FIG. 35 is a cross-sectional view of the structure of the conventional SJ-MOSFET, along cutting line B-B′. FIG. 36 is a cross-sectional view of the structure of the conventional SJ-MOSFET, along cutting line C-C′. The plan views in FIGS. 31 to 33 depict the structure at the depths D-D′, E-E′, F-F′ indicted in the cross-sectional views depicted in FIGS. 34 to 36, respectively, and the cross-sectional views in FIGS. 34 to 36 depict the structure along cutting lines A-A′, B-B′, C-C′ indicated in the plan views in FIGS. 31 to 33, respectively. Further, in FIGS. 31 to 36, in a device structure of an active region 150, depiction of a MOS gate (metal-oxide-semiconductor insulated gate) structure and the like of a front side of a semiconductor substrate 180 is omitted.

As depicted in FIGS. 31 to 36, in the conventional SJ-MOSFET, an n-type buffer layer 102 is provided in an n⁺⁺-type semiconductor substrate 101 having a high dopant concentration, and an n-type drift layer 170 in which multiple epitaxial layers are stacked is provided on the n-type buffer layer 102. From the surface of the n⁻-type drift layer 170, in a direction to the n⁺⁺-type semiconductor substrate 101, p-type column regions 104 and n-type column regions 103 are provided. While the n-type buffer layer 102 is provided between the n⁺⁺-type semiconductor substrate 101 and the p-type column regions 104 and the n-type column regions 103, the p-type column regions 104 and the n-type column regions 103 may be in contact with the n⁺⁺-type semiconductor substrate 101.

Further, in the n-type drift layer 170, a parallel structure (hereinafter, a parallel pn region 120) is provided in which p-type regions (hereinafter, the p-type column regions 104) and n-type regions (hereinafter, the n-type column regions 103) arranged in a direction orthogonal to a substrate main surface and having a narrow width in a plane parallel to the substrate main surface are arranged repeatedly alternating with each other in a plane parallel to the substrate main surface. The p-type column regions 104 and the n-type column regions 103 configuring the parallel pn region 120 are regions in which the dopant concentration is increased corresponding to the n-type buffer layer 102. In the parallel pn region 120, the dopant concentrations contained by the p-type column regions 104 and the n-type column regions 103 are made substantially equal, whereby in an off-state, a pseudo-non-doped layer may be created to achieve high breakdown voltage.

In the SJ-MOSFET, on the parallel pn region 120 of the active region 150 through which current flows when a device is formed and is in an on-state, p⁺-type base regions (not depicted) are provided. In the p⁺-type base regions, n⁺-type source regions (not depicted) are provided. Further, at the surfaces of the p⁺-type base regions and the surfaces of the n-type column regions 103, a gate insulating film (not depicted) is provided. On the surface of the gate insulating film, a gate electrode (not depicted) is provided and an interlayer insulating film (not depicted) is provided so as to cover the gate electrode. Further, on the n⁺-type source regions, a source electrode (not depicted) is provided and at a back surface of the n⁺⁺-type semiconductor substrate 101, a drain electrode (not depicted) is provided. Here, the n⁺⁺-type semiconductor substrate 101 corresponds to a drain region.

In the SJ-MOSFET, in a termination region 160 surrounding a periphery of the active region 150 in a plan view, the parallel pn region 120 is provided in the n-type drift layer 170 similar to the active region 150 and an n-type termination R region 130 is provided so as to surround the parallel pn region 120 in a plan view. The n⁻-type termination R region 130 is provided from the surface of the n⁻-type drift layer 170 to a depth of a lower surface of the n-type drift layer 170 and is in contact with the n-type buffer layer 102. Between the n-type termination R region 130 and an end of the semiconductor substrate 180, an n-type region 115 is provided so as to surround the n-type termination R region 130 in a plan view. The n-type region 115 is provided from the surface of the n-type drift layer 170 to the depth of the lower surface of the n⁻-type drift layer 170 and is in contact with the n-type buffer layer 102. Here, the n-type region 115 may have a dopant concentration that is a same as that of the n-type buffer layer 102. At the surface of the n-type region 115, an n⁺-type region (not depicted) functioning as a channel stopper is provided so as to surround the n-type termination R region 130 in a plan view. An oxide film is provided on the parallel pn region 120 and the n⁺-type region, and a drain electrode (not depicted) is provided at the back surface of the n⁺⁺-type semiconductor substrate 101.

As described, in the SJ-MOSFET for power conversion, a vertical structure including, at a front surface, the source electrode connected to the p⁺-type base regions and at a back surface, the drain electrode connected to the n⁺⁺-type semiconductor substrate 101 is mainstream and when a voltage is applied between the drain and source, a depletion layer spreads between the p⁺-type base regions and the n-type buffer layer 102, maintaining a breakdown voltage. The depletion layer spreads in a vertical direction from the source electrode side to the drain electrode side and also concurrently spreads in a horizontal direction and thus, in the termination region 160, a measure such as a termination structure for controlling the spreading of the depletion layer is necessary. Device characteristics are mainly determined by the characteristics of the active region 150 and therefore, to maximize device performance, in general, the breakdown voltage of the termination region 160 is maintained higher than a breakdown voltage of the active region 150.

The magnitude of the breakdown voltage is determined by the width of the depletion layer, which is dependent on dopant concentration and when the dopant concentration is low, the depletion layer is wide and the breakdown voltage may be maintained relatively high. When the depletion layer spreading in the horizontal direction reaches the termination region 160, punch-through occurs and the breakdown voltage cannot be maintained and thus in the termination region 160, the spreading of the depletion layer has to be stopped. When the spreading of the depletion layer is stopped abruptly, avalanche current is generated due to electric field concentrating, possibly leading to destruction of the device, thus, to gradually stop the depletion layer, the width of the termination region 160 has to be increased, which increases the size of the device and therefore, the spreading of the depletion layer has to be suppressed in a balanced manner. In the SJ-MOSFET, in the n⁻-type drift layer 170, a parallel pn column region 120 is further disposed in the termination region 160 and therefore, adjustment of the concentration and shape of pn junctions is important.

In the termination region 160 of the conventional SJ-MOSFET, the n-type drift layer 170 is separated into two types of structures: a structure having a parallel relationship with the parallel pn column region 120 and a structure having a horizontal relationship therewith. The manner in which the depletion layer spreads and the electric field distribution in each of the regions differs and thus, a problem arises in that design is complicated.

Embodiments of a superjunction semiconductor device according to the present disclosure solving the problems associated with the described conventional superjunction semiconductor device are described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. In the description of the embodiments below and the accompanying drawings, main portions that are identical are given the same reference numerals and are not repeatedly described. Further, with consideration of variation in manufacturing, description indicating the same or equal may be within 5%.

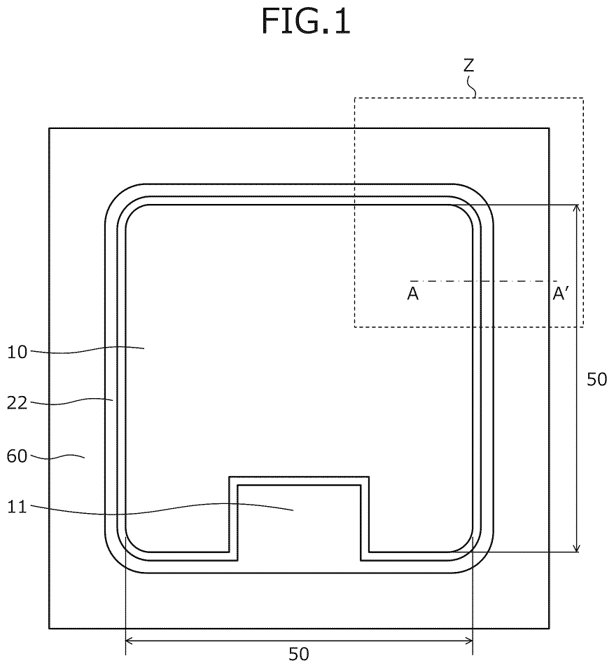

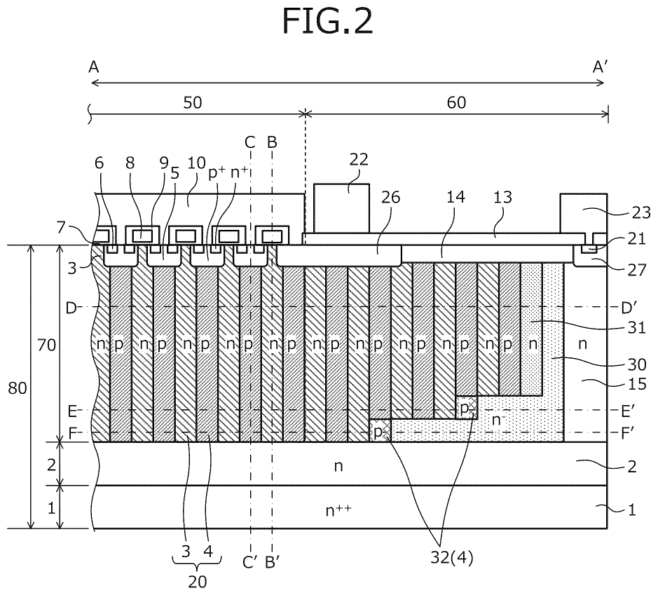

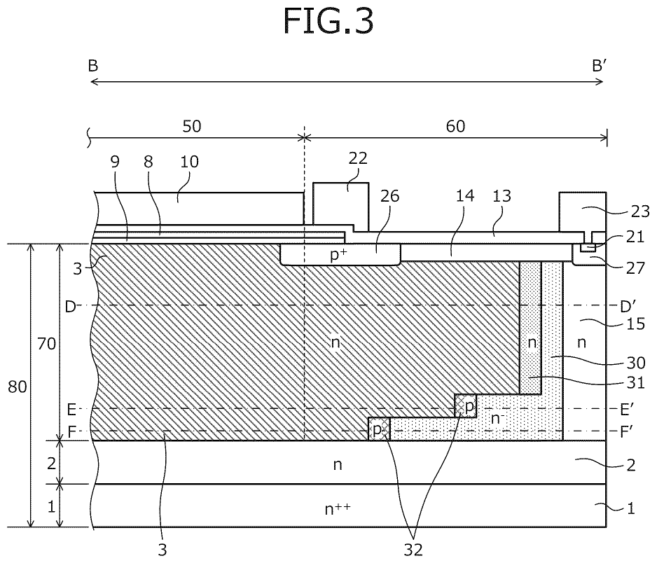

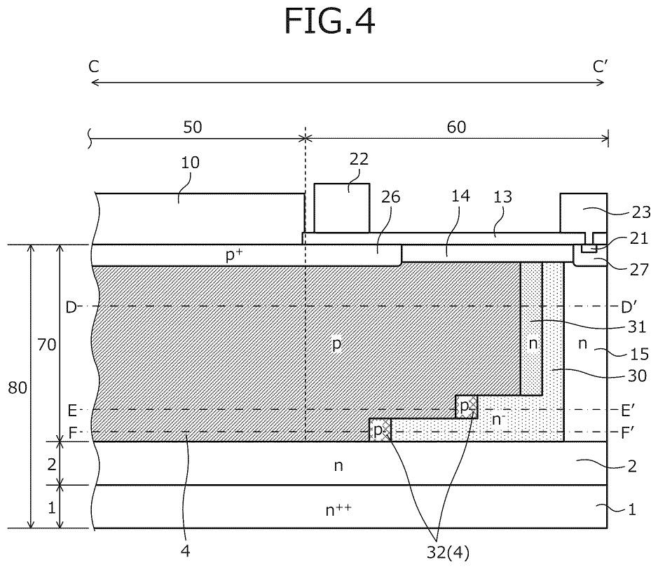

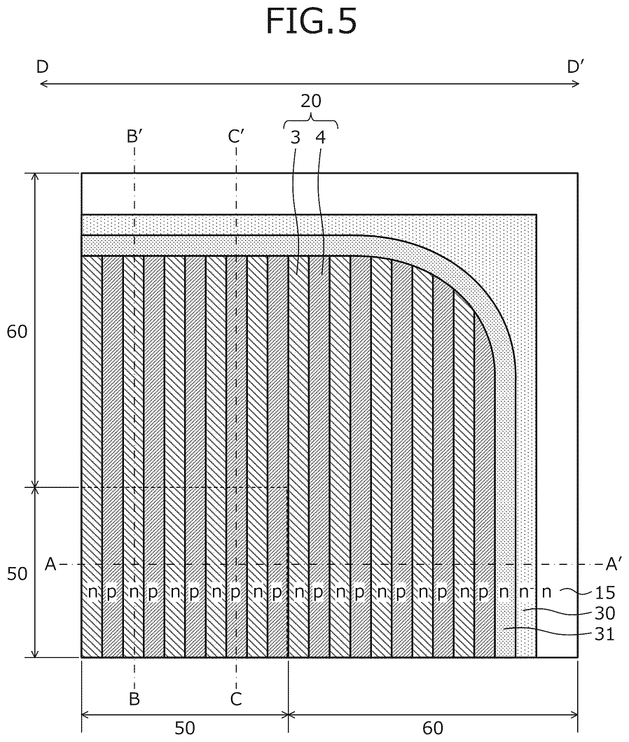

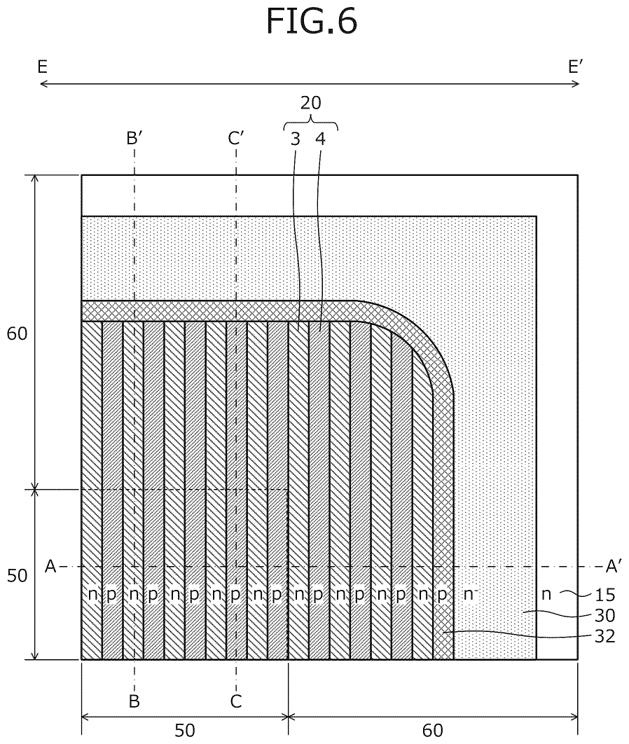

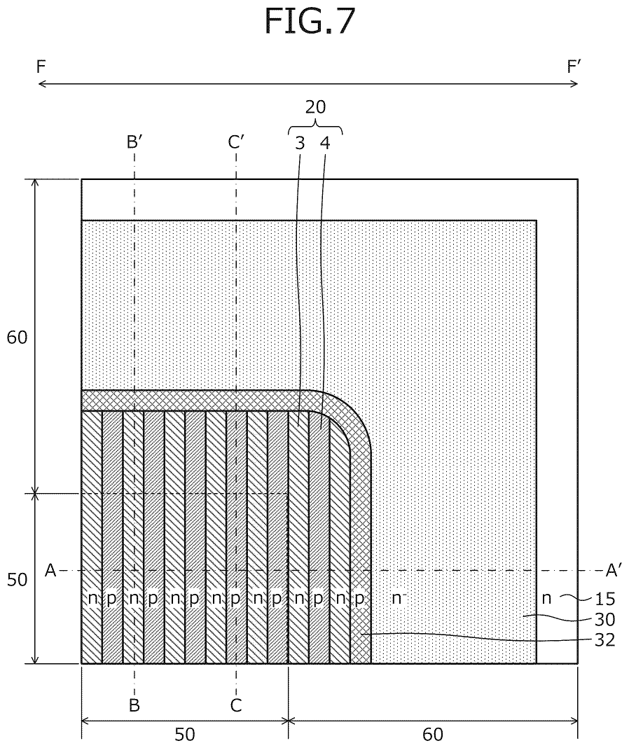

A superjunction semiconductor device according to the present disclosure is described taking a SJ-MOSFET fabricated (manufactured) using silicon (Si) as an example. FIG. 1 is a top view the SJ-MOSFET according to the embodiment. FIG. 2 is a cross-sectional view depicting a first structure of the SJ-MOSFET according to the embodiment, along cutting line A-A′. FIG. 3 is a cross-sectional view depicting the first structure of the SJ-MOSFET according to the embodiment, along cutting line B-B′. FIG. 4 is a cross-sectional view depicting the first structure of the SJ-MOSFET according to the embodiment, along cutting line C-C′. FIG. 5 is a plan view depicting the first structure of the SJ-MOSFET according to the embodiment, along cutting line D-D′. FIG. 6 is a plan view depicting the first structure of the SJ-MOSFET according to the embodiment, along cutting line E-E′. FIG. 7 is a plan view depicting the first structure of the SJ-MOSFET according to the embodiment, along cutting line F-F′. The cross-sectional view in FIG. 2 depicts the structure along cutting line A-A′ in FIG. 1. The cross-sectional views in FIGS. 3 and 4 depict the structure along, respectively, cutting lines B-B′, C-C′ in FIG. 2. The plan views in FIGS. 5 to 7 depict, respectively, enlarged views of a region Z in FIG. 1, at depths indicated by cutting lines D-D′, E-E′, F-F′ in the cross-sectional views in FIGS. 2 to 4.

The SJ-MOSFET according to the embodiment is a SJ-MOSFET having metal-oxide-semiconductor (MOS) gates in a later-described semiconductor substrate 80 containing silicon (Si), the MOS gates being at a front surface (surface having p⁺-type base regions 5) of the semiconductor substrate 80. The SJ-MOSFET, as depicted in FIG. 1, includes an active region 50 and a termination region 60 surrounding a periphery of the active region 50 in a plan view. The active region 50 is a region through which current flows during an on-state. The termination region 60 is a region that relaxes electric field of a front side of the semiconductor substrate 80 and sustains the breakdown voltage. In the termination region 60, gate wiring 22 is provided so as to surround the active region 50 in a plan view. Further, a later-described oxide film 13 and channel stopper electrode 23 are provided in the termination region 60. The active region 50 is a region that, in a plan view, is surrounded by ends of a source electrode 10, the ends thereof closest to ends of the SJ-MOSFET depicted in FIG. 1. In the active region 50, the source electrode 10 and a gate pad 11 connected to the gate wiring 22 are provided. The gate wiring 22 and the gate pad 11 are electrically insulated from the source electrode 10. Further, at the surface of the SJ-MOSFET according to the embodiment, a surface protective film (not depicted) such as a polyimide may be provided. In the surface protective film, an opening exposing the surface of the source electrode 10 and the surface of the gate pad 11 is provided. Furthermore, in the SJ-MOSFET according to the embodiment, a temperature sensing diode (not depicted), a current sensor (not depicted), etc. may be provided.

FIG. 2 is a cross-sectional view along cutting line A-A′ in FIG. 1. In FIG. 2, only four unit cells (functional units of the device) are depicted in the active region 50 and other adjacent unit cells are not depicted. An n⁺⁺-type semiconductor substrate (semiconductor substrate of a first conductivity type) 1, for example, is a single crystal silicon substrate doped with phosphorus (P). An n-type buffer layer (first semiconductor layer of the first conductivity type) 2 has a dopant concentration that is lower than a dopant concentration of the n⁺⁺-type semiconductor substrate 1 and, for example, is a low-concentration n-type layer doped with phosphorus. On the n-type buffer layer 2, an n-type drift layer (second semiconductor layer of the first conductivity type) 70 in which multiple epitaxial layers are stacked is provided. The n⁻-type drift layer 70 has a dopant concentration lower than the dopant concentration of the n-type buffer layer 2 and, for example, is a low-concentration n⁻-type layer doped with phosphorus. Hereinafter, the n⁺⁺-type semiconductor substrate 1, the n-type buffer layer 2, and the n⁻-type drift layer 70 combined are assumed as the semiconductor substrate 80. In the semiconductor substrate 80, at the front surface thereof, a metal-oxide film-semiconductor insulated gate (MOS gate) structure (device structure) is formed. Further, at a back surface (back surface of the n⁺⁺-type semiconductor substrate 1) of the semiconductor substrate 80, a drain electrode (not depicted) is provided. Here, the n⁺⁺-type semiconductor substrate 1 corresponds to a drain region.

In the active region 50 of the semiconductor substrate 80, a parallel pn region 20 is provided. In the parallel pn region 20, n-type column regions 3 and p-type column regions 4 are disposed repeatedly alternating with each other. The n-type column regions 3 and the p-type column regions 4 are provided from the surface of the semiconductor substrate 80 in a direction to the n⁺⁺-type semiconductor substrate 1. The n-type column regions 3 and the p-type column regions 4 are formed in the n-type drift layer 70. While the n-type buffer layer 2 is provided between the n⁺⁺-type semiconductor substrate 1 and the n-type column regions 3 and the p-type column regions 4, the n-type column regions 3 and the p-type column regions 4 may be in contact with the n⁺⁺-type semiconductor substrate 1.

Further, each of the p⁺-type base regions 5 is provided in a surface layer of a corresponding one of the p-type column regions 4, and n⁺-type source regions 6 are selectively provided in a surface layer of each of the p⁺-type base regions 5. In each of the p⁺-type base regions 5, portions thereof are each between a corresponding one the n⁺-type source regions 6 and a corresponding one the n-type column regions 3 and at surfaces of said portions, gate electrodes 8 are provided via gate insulating films 7. Each of the gate electrodes 8 may be further provided at the surface of a corresponding one the n-type column regions 3 via the gate insulating films 7. In the surface layer of each of the p⁺-type base regions 5, the n⁺-type source regions 6 may be selectively provided. In regions between the n⁺-type source regions 6, p⁺⁺-type contact regions (not depicted) having a dopant concentration higher than a dopant concentration of the p⁺-type base regions 5 may be provided. The p⁺-type base regions 5, the n⁺-type source regions 6, and the p⁺⁺-type contact regions (not depicted) may be provided in stripe-like shapes extending along a direction of view in FIG. 2.

An interlayer insulating film 9 is provided at the front side of the semiconductor substrate 80 so as to cover the gate electrodes 8. The source electrode 10 is in contact with the n⁺-type source regions 6 and the p⁺-type base regions 5 via contact holes opened in the interlayer insulating film 9 and is electrically connected to the n⁺-type source regions 6 and the p⁺-type base regions 5.

The source electrode 10 is electrically insulated from the gate electrodes 8 by the interlayer insulating film 9. On the source electrode 10, for example, a protective film (not depicted) such as a passivation film containing a polyimide is selectively provided.

In the termination region 60 of the SJ-MOSFET, similar to the active region 50, the parallel pn region 20 is provided. Preferably, the dopant concentration of the parallel pn region 20 of the termination region 60 may be lower than or a same as the dopant concentration of the parallel pn region 20 provided in the active region 50. Further, preferably, the dopant concentration of the parallel pn region 20 of the termination region 60 may progressively decrease in a direction away from the active region 50. Preferably, the dopant concentration of the parallel pn region 20 of the termination region 60 may be ½ times to ⅓ times the dopant concentration of the parallel pn region 20 of the active region 50. An outermost n-type column region of the parallel pn region 20 provided in the termination region 60 constitutes an n-type annular region (first semiconductor region of the first conductivity type) 31.

The depth of each of the n-type column regions 3 and the p-type column regions 4 of the parallel pn region 20 of the termination region 60 becomes shallower from the surface of the n-type drift layer 70 stepwise, the closer the n-type column regions 3 and the p-type column regions 4 of the parallel pn region 20 of the termination region 60 are to the ends of the SJ-MOSFET. An n⁻-type termination R region 30 is provided between the n-type buffer layer 2 and the shallower portions of the n-type column regions 3 and the p-type column regions 4.

Further, in the parallel pn region 20 that becomes shallower stepwise in directions to the ends of the SJ-MOSFET, there are locations where the depth of one of the p-type column regions 4 is deeper than the depth of an adjacent one of the n-type column regions 3. In a bottom portion of each of the p-type column regions 4 having a depth deeper than the depth of an adjacent one of the n-type column regions 3, one of multiple p-type annular regions (second semiconductor regions of a second conductivity type) 32 is provided.

A dopant concentration of the p-type annular regions 32 may be a same as a dopant concentration of the p-type column regions 4 or may be lower than the dopant concentration of the p-type column regions 4. Outside of the parallel pn region 20, the n-type termination R region 30 having a dopant concentration lower than the dopant concentration of the n-type buffer layer 2 is provided so as to surround the parallel pn region 20 in a plan view. The n-type termination R region 30 is provided from the surface of the n-type drift layer 70 to a depth of a lower surface of the n⁻-type drift layer 70 and is in contact with an upper surface of the n-type buffer layer 2. The dopant concentration of the n-type termination R region 30 may be lower than a dopant concentration of the n-type column regions 3 of the termination region 60 or may be a same as the dopant concentration of the n-type column regions 3 of the termination region 60.

Outside of the n-type termination R region 30, an n-type region 15 having a dopant concentration higher than the dopant concentration of the n⁻-type termination R region 30 is provided. The n-type region 15 is provided from the surface of the n-type drift layer 70 to the depth of the lower surface of the n⁻-type drift layer 70 and is in contact with the upper surface of the n-type buffer layer 2. A dopant concentration of the n-type region 15 is a same as the dopant concentration of the n-type buffer layer 2.

At the surface of the n-type region 15, a p⁺-type region 27 and a p⁺-type region 21 functioning as a channel stopper are provided so as to surround the n⁻-type termination R region 30 in a plan view. The p⁺-type region 27 is provided from the surface of the n⁻-type drift layer 70 in a direction to the n⁺⁺-type semiconductor substrate 1 and is in contact with a later-described n-type region 14. A bottom of the p⁺-type region 27 is provided in the n-type region 15. Preferably, a depth of the p⁺-type region 27 may be deeper than a depth of the n-type region 14 and preferably, may be a same as a depth of a later-described p⁺-type well region 26. Further, a dopant concentration of the p⁺-type region 27 may be a same as a dopant concentration of the p⁺-type well region 26.

The p⁺-type region 21 is provided from the surface of the n-type drift layer 70 in a direction to the n⁺⁺-type semiconductor substrate 1. The p⁺-type region 21 is provided at the surface of the p⁺-type region 27, a bottom and side surfaces of the p⁺-type region 21 being in contact with the p⁺-type region 27. Preferably, a dopant concentration of the p⁺-type region 21 may be higher than or a same as the dopant concentration of the p⁺-type region 27. In an instance in which the p⁺⁺-type contact regions (not depicted) are provided in the active region 50, preferably, the dopant concentration of the p⁺-type region 21 may be a same as a dopant concentration of the p⁺⁺-type contact regions (not depicted). Further, preferably, the p⁺-type region 21 may be provided to a same depth as a depth of the p⁺⁺-type contact regions (not depicted) of the active region 50.

At the surface of the parallel pn region 20 of the termination region 60, the p⁺-type well region 26 and the n-type region 14 are provided. The p⁺-type well region 26 is provided across the active region 50 and the termination region 60. In a first structure, while the p⁺-type well region 26 is provided to a same depth as the depth of the p⁺-type base regions 5 of the active region 50, the p⁺-type well region 26 may be provided to a position deeper than are bottoms of the p⁺-type base regions 5 of the active region 50. The dopant concentration of the p⁺-type well region 26 is a same as the dopant concentration of the p⁺-type base regions 5. The dopant concentration of the p⁺-type well region 26, preferably, may be lower than the dopant concentration of the p⁺-type base regions 5.

A dopant concentration of the n-type region 14 is lower than or a same as the dopant concentration of the n-type column regions 3 of the active region 50. The dopant concentration of the n-type region 14 is higher than or a same as the dopant concentration of the n-type termination R region 30. At respective surfaces of the p⁺-type well region 26, the n-type region 14, the p⁺-type region 21, and the p⁺-type region 27, the oxide film 13 is provided. Further, in the termination region 60, at the surface of the oxide film 13, the channel stopper electrode 23 electrically connected to the p⁺-type region 21 and the gate wiring 22 electrically connected to the gate electrodes 8 are provided.

FIGS. 3 and 4 are cross-sectional views along cutting lines B-B′ and C-C′ in a direction of view FIG. 2 depicting a cross-section along cutting line A-A′. FIG. 3 is a cross-sectional view of one of the n-type column regions 3 and corresponds to a cross-sectional view along cutting line B-B′ depicted in later-described FIGS. 5 to 7. FIG. 4 is a cross-sectional view of one of the p-type column regions 4 and corresponds to a cross-sectional view along cutting line C-C′ depicted in later-described FIGS. 5 to 7.

As depicted in FIGS. 3 and 4, the n-type column regions 3 and the p-type column regions 4 are provided in stripe-like shapes. Further, the p⁺-type well region 26, the p⁺-type region 21, and the p⁺-type region 27 are provided in annular shapes in a surface layer of the semiconductor substrate 80. Further, the n-type region 14 is provided between the p⁺-type well region 26 and the p⁺-type region 27. At respective upper surfaces of the p⁺-type well region 26, the n-type region 14, the p⁺-type region 21, and the p⁺-type region 27, the oxide film 13 is provided. At an upper surface of the oxide film 13, the gate wiring 22 electrically connected to the gate electrodes 8 is provided.

Further, at the upper surface of the oxide film 13, the channel stopper electrode 23 having an annular shape is provided. The channel stopper electrode 23 is electrically connected to the p⁺-type region 27 via the p⁺-type region 21 through a contact hole provided in the oxide film 13. The p-type annular regions 32 are provided having annular shapes. In the termination region 60, an innermost one of the p-type annular regions 32 is provided closest to the active region 50 and has a lower surface that is in contact with the n-type buffer layer 2 and a side surface that is in contact with the n-type termination R region 30. In the termination region 60, an outer one of the p-type annular regions 32, provided relatively closer to the ends of the SJ-MOSFET, has a lower surface and side surface in contact with the n⁻-type termination R region 30.

FIG. 5 is a plan view at a depth indicated by cutting line D-D′ depicted in FIGS. 2 to 4. In the embodiment, in the termination region 60, bottom portions or a portion of the parallel pn region 20, positioned closest to the ends of the SJ-MOSFET is formed in an annular shape maintaining a constant distance from the active region 50 and is connected to parallel columns of a same conductivity type. As a result, the electric field distributions for the differing structures of the termination region 60 may be made uniform. Columns of the same conductivity type are the n-type column regions 3 when the region formed in an annular shape is an n-type and are the p-type column regions 4 when the region formed in an annular shape is a p-type.

In the embodiment, the n-type annular region 31 is provided so as to surround the parallel pn region 20 in a plan view. The n-type column regions 3 of the parallel pn region 20 provided in stripe-like shapes are in contact with the n-type annular region 31, which has an annular shape. A dopant concentration of the n-type annular region 31 is a same as the dopant concentration of the n-type column regions 3 of the termination region 60. Preferably, the dopant concentration of the n-type annular region 31 may be lower than the dopant concentration of the n-type column regions 3 of the active region 50. Further, the dopant concentration of the n-type annular region 31 is higher than the dopant concentration of the n⁻-type termination R region 30.

FIGS. 6 and 7 are a plan views at depths indicated by cutting lines E-E′ and F-F′ depicted in FIGS. 2 to 4. As the region formed in an annular shape, the p-type annular regions 32 having an annular shape surrounding the parallel pn region 20 in a plan view are provided at bottom portions of the parallel pn region 20 and are connected to the p-type column regions 4 that are parallel. Here, in each location where the n-type column regions 3 become shallower stepwise, one of the p-type annular regions 32 is provided at innermost bottom portions of the p-type column regions 4, closest to the active region 50.

FIG. 6 depicts an outermost one of the p-type annular regions 32 in the termination region 60 depicted in FIGS. 2 to 4, the outermost one having an annular shape and being disposed closest to the ends of the SJ-MOSFET. The outermost p-type annular region 32 is provided in an annular shape and has a lower surface that is in contact with the n⁻-type termination R region 30. FIG. 7 depicts an innermost one of the p-type annular regions 32, provided closer to the active region 50 than is the p-type annular region 32 depicted in FIG. 6 and having an annular shape. This p-type annular region 32 provided relatively closer to the active region 50 has a lower surface that is in contact with the n-type buffer layer 2.

In the termination region 60, depletion occurs in a fan-like shape centered on the source electrode 10 of the active region 50, extending in a vertical direction to the drain electrode and horizontally toward the ends of the device. For example, as depicted in FIG. 2, in a termination structure parallel to the parallel pn region 20 in the n⁻-type drift layer 70, the direction of progression of the depletion layer and pn junction surfaces match and thus, the depletion layer easily spreads, however, in a termination structure that is orthogonal as depicted in FIGS. 3 and 4, the pn junctions become obstacles with respect to the direction of progression of the depletion layer. Thus, in the orthogonal termination structure, spreading of the depletion layer is difficult and a difference in breakdown voltages of the two structures may arise. In the embodiment, a portion of the parallel pn region 20 is connected to parallel columns of the same conductivity type, whereby the manner in which the depletion layer spreads and the electric field distribution of the differing termination structures are made uniform, enabling a difference in the breakdown voltages of the differing structures to be reduced. Furthermore, connection of the parallel columns of the same conductivity type spreads (distributes) current paths for excess carriers discharged during avalanche breakdown and reverse recovery, whereby current may be suppressed from concentrating.

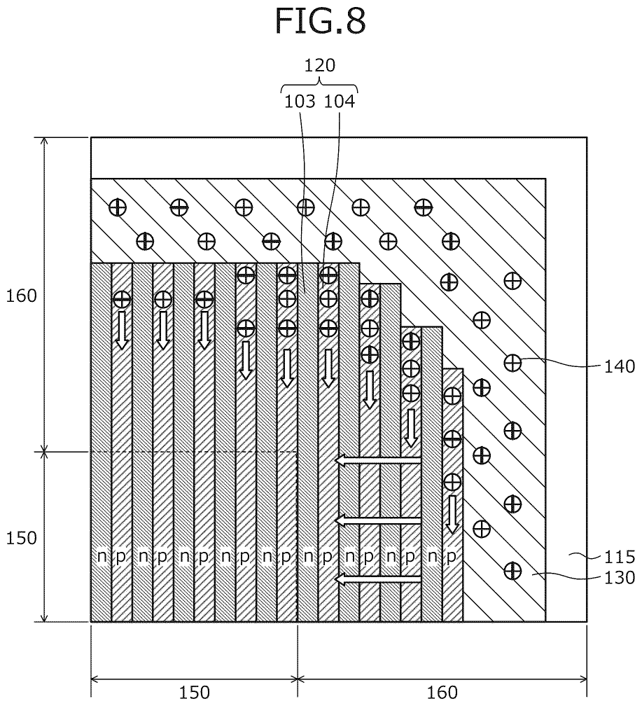

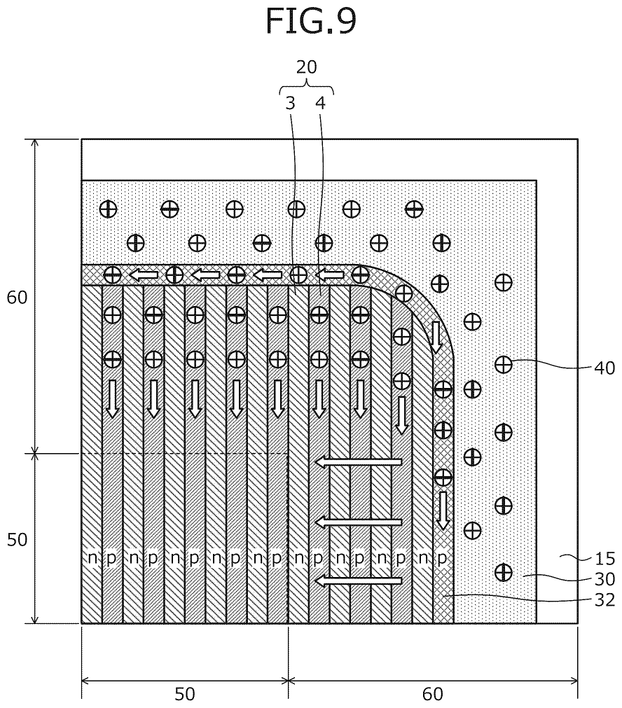

FIG. 8 is a plan view depicting a conceptual image of paths of hole carriers remaining in the termination region during a reverse recovery process of the conventional SJ-MOSFET, the paths being at a depth indicated by cutting line E-E′ in the cross-sectional views depicted in FIGS. 34 to 36. FIG. 9 is a plan view depicting a conceptual image of paths of hole carriers remaining in the termination region during a reverse recovery process in the SJ-MOSFET according to the embodiment, the paths being at a depth indicated by cutting line E-E′ in the cross-sectional views depicted in FIGS. 2 to 4.

As depicted in FIG. 8, in the conventional SJ-MOSFET, while the p-type column regions 104 having stripe-like shapes are independent or connected by a RESURF structure or a p⁺-type well region near the surface, in the back side, paths for hole carriers 140 are difficult to distribute. As a result, the hole carriers 140 concentrate at the p-type column regions 104 near the structure parallel to the parallel pn region 120 and hole current tends to concentrate and thus, there is a concern that reverse recovery capability may decrease.

In contrast, as depicted in FIG. 9, in the SJ-MOSFET according to the embodiment, the p-type annular regions 32 are provided, whereby in the back side as well, paths connecting the p-type column regions 4 are increased thereby distributing paths for hole carriers 40. As a result, the hole carriers 40 pass through the p-type annular regions 32, whereby the hole current may be distributed without the hole carriers 40 concentrating in the p-type column regions 4 close to the structure parallel to the parallel pn region 20. In FIG. 9, while an effect of the p-type annular regions 32 is depicted, the n-type annular region 31 may similarly encourage distribution of hole current.

Further, adjacent columns are connected, whereby the electric field distribution of the termination region 60 may be made uniform, obtaining an effect that a difference in the breakdown voltage of the termination portion parallel to the stripe-like shapes of the parallel pn region 20 parallel to the n⁻-type drift layer 70 and the breakdown voltage of the termination portion orthogonal to the stripe-like shapes of the parallel pn region 20 is reduced.

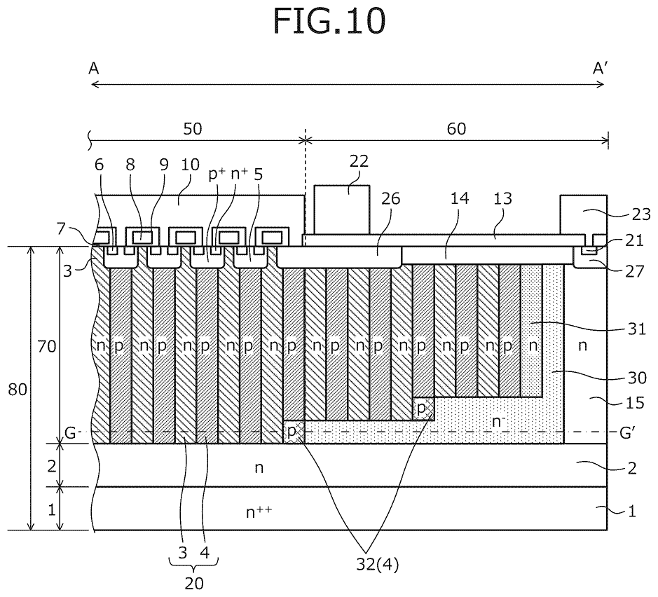

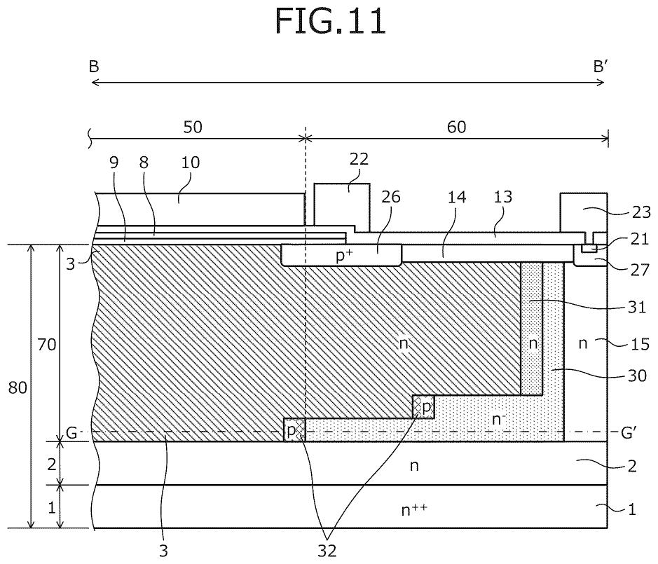

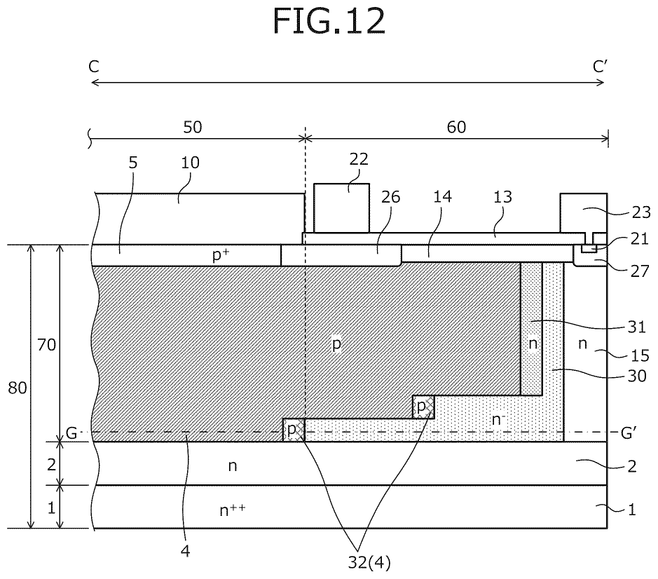

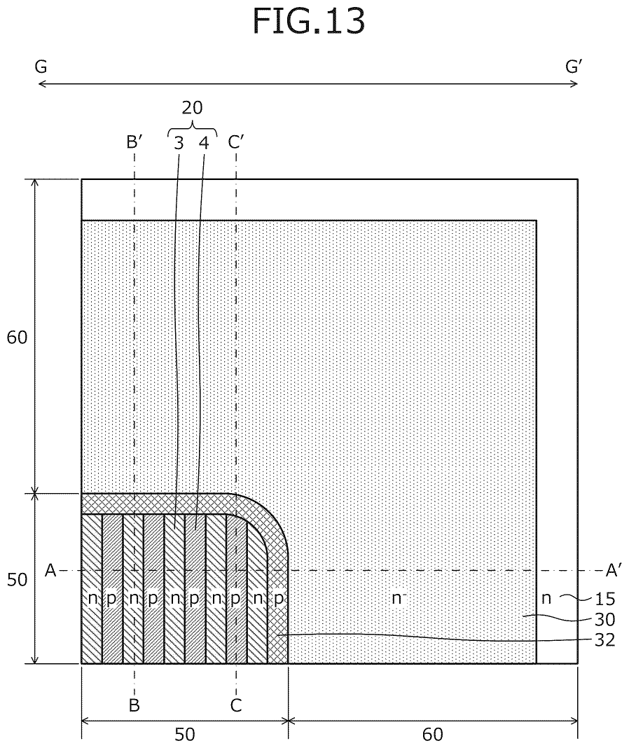

FIG. 10 is a cross-sectional view depicting a second structure of the SJ-MOSFET according to the embodiment, along cutting line A-A′. FIG. 11 is a cross-sectional view depicting the second structure of the SJ-MOSFET according to the embodiment, along cutting line B-B′. FIG. 12 is a cross-sectional view depicting the second structure of the SJ-MOSFET according to the embodiment, along cutting line C-C′. FIG. 13 is a plan view depicting the second structure at a depth indicated by cutting line G-G′ depicted in the cross-sectional views of the second structure in FIGS. 10 to 12. In the second structure, the p-type annular regions 32 have an annular shape surrounding the active region 50 in a plan view and one is provided in a bottom portion of an outermost one of the p-type column regions 4 provided in the active region 50.

In the second structure, similar to the first structure, the depth of each of the n-type column regions 3 and the p-type column regions 4 of the parallel pn region 20 of the termination region 60 becomes shallower from the surface of the n-type drift layer 70 stepwise, the closer the n-type column regions 3 and the p-type column regions 4 of the parallel pn region 20 of the termination region 60 are to the ends of the SJ-MOSFET. The second structure differs from the first structure in that one of the p-type annular regions 32 is provided in the active region 50. In the first structure, the depth of each of the n-type column regions 3 and the p-type column regions 4 of the parallel pn region 20 in a portion of the termination region 60 is a same as the depth of each of the n-type column regions 3 and the p-type column regions 4 of the active region 50. On the other hand, in the second structure, in the termination region 60, the depth of each of the n-type column regions 3 and the p-type column regions 4 of the parallel pn region 20 is shallower than the depth of each of the n-type column regions 3 and the p-type column regions 4 of the active region 50.

In the second structure, the p-type annular region 32 of the active region 50 is provided in the bottom portion of the outermost one of the p-type column regions 4 of the active region 50. The bottom of the p-type annular region 32 provided in the active region 50 is in contact with the n-type buffer layer 2. A side surface of the p-type annular region 32 provided in the active region 50 is in contact with the n⁻-type termination R region 30. Lower surfaces of all the n-type column regions 3 and the p-type column regions 4 of the termination region 60 are in contact with the n-type termination R region 30. In the first structure and the second structure, the same number of the p-type annular regions 32 are provided and the same number of the n-type column regions 3 and the p-type column regions 4 of the termination region 60 are provided. In the second structure, one of the p-type annular regions 32 is provided in the active region 50, whereby the number of the n-type column regions 3 and the p-type column regions 4 of the termination region 60, having the same depth is increased as compared to the first structure.

As described, in the termination region 60, the number of the n-type column regions 3 and the p-type column regions 4 having the same depth is increased as compared to the first structure, whereby variation of the electric field distribution of the termination region 60 becomes gradual and electric field does not easily concentrate. Further, all the n-type column regions 3 and the p-type column regions 4 of the termination region 60 are shallower than the n-type column regions 3 and the p-type column regions 4 of the active region 50 and lower surfaces thereof are in contact with the n-type termination R region 30, whereby an effect may be obtained in that electric field may be prevented from concentrating at the outermost one of the p-type column regions 4 (the p-type annular regions 32) provided in the active region 50.

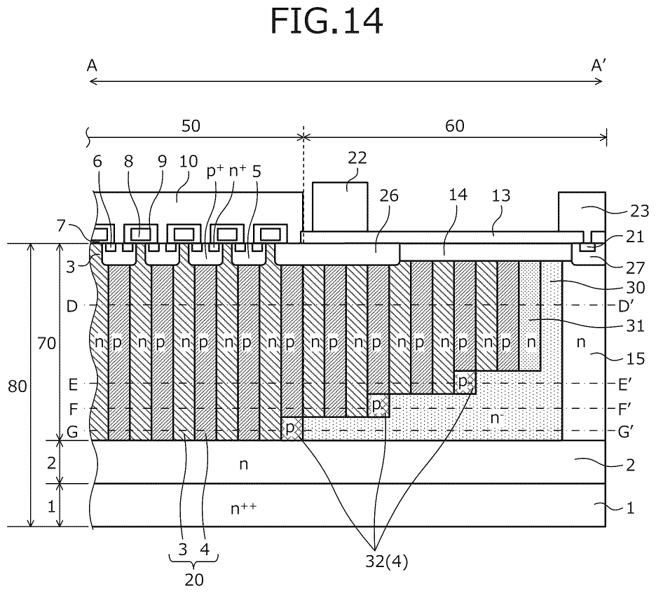

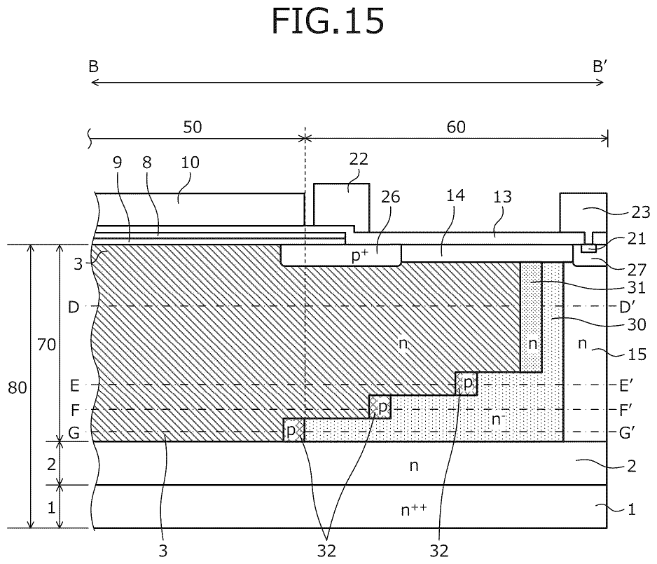

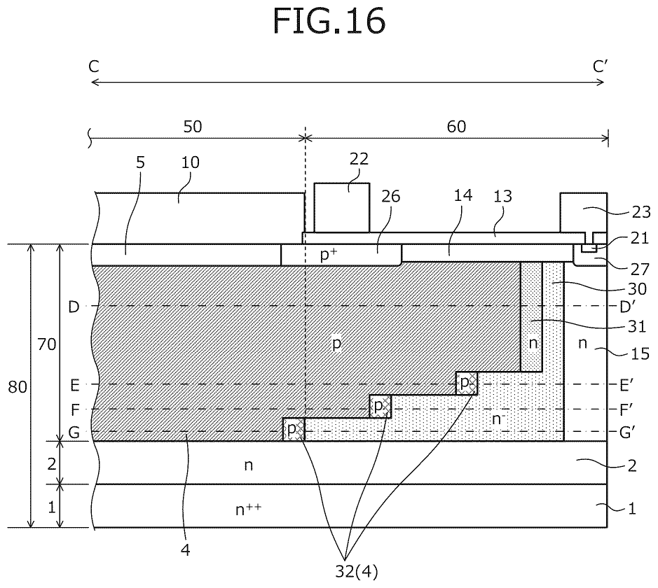

FIG. 14 is a cross-sectional view depicting a third structure of the SJ-MOSFET according to the embodiment, along cutting line A-A′. FIG. 15 is a cross-sectional view depicting the third structure of the SJ-MOSFET according to the embodiment, along cutting line B-B′. FIG. 16 is a cross-sectional view depicting the third structure of the SJ-MOSFET according to the embodiment, along cutting line C-C′. Plan views of the third structure are omitted. The cross-sectional views depicted in FIGS. 14 to 16 depict the structure at positions indicated by cutting lines A-A′, B-B′, C-C′, and G-G′ in the plan views in FIGS. 5 to 7, and 13, respectively.

In the second structure in FIGS. 10 to 13, the depth of each of the n-type column regions 3 and the p-type column regions 4 of the parallel pn region 20 in the termination region 60 becomes shallower in two steps similar to the first structure. In other words, the depths of the n-type column regions 3 and the p-type column regions 4 of the termination region 60 include two types: a depth that is shorter than the depths of the n-type column regions 3 and the p-type column regions 4 of the active region 50 and a depth that even shorter. On the other hand, in the third structure in FIGS. 14 to 16, the depth of each of the n-type column regions 3 and the p-type column regions 4 of the parallel pn region 20 of the termination region 60 becomes shallower in three steps. In other words, the depths of the n-type column regions 3 and the p-type column regions 4 of the termination region 60 include three types: a depth that is shorter than the depth of the n-type column regions 3 and the p-type column regions 4 of the active region 50, a depth that is further shorter, and a depth that is shortest. In each location where the n-type column regions 3 become shallower stepwise, one of the p-type annular regions 32 is provided in innermost bottom portions of the p-type column region 4, closest to the active region 50 and thus, in the third structure, the p-type annular regions 32 are provided at three locations. The p-type annular regions 32 have an effect of distributing concentration of hole current and thus, the third structure having a relatively large number of the p-type annular regions 32 may further distribute hole current as compared to the first structure and the second structure and may further reduce a difference in the breakdown voltage of the termination portion parallel to and the breakdown voltage of the termination portion orthogonal to the stripe-like shapes of the parallel pn region 20 parallel to the n-type drift layer 70.

In FIGS. 14 to 16, the innermost one of the p-type annular regions 32 is provided in the bottom portion of outermost ones of the p-type column regions 4 provided in the active region 50, the innermost one of the p-type annular regions 32 being provided so as to surround the active region in a plan view. Further, while the depth of each of the n-type column regions 3 and the p-type column regions 4 becomes shallower in three steps, the number of steps may be four or more.

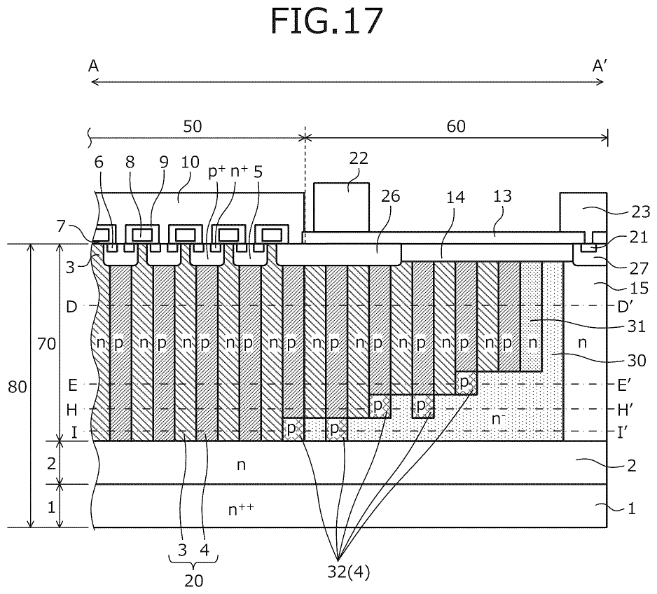

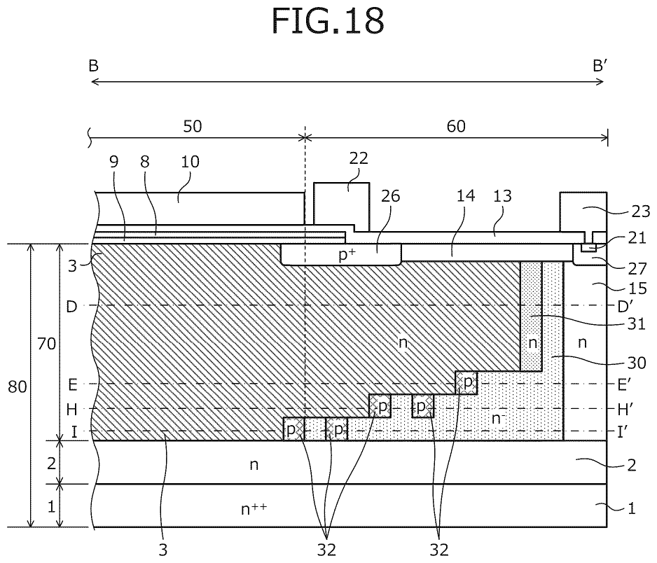

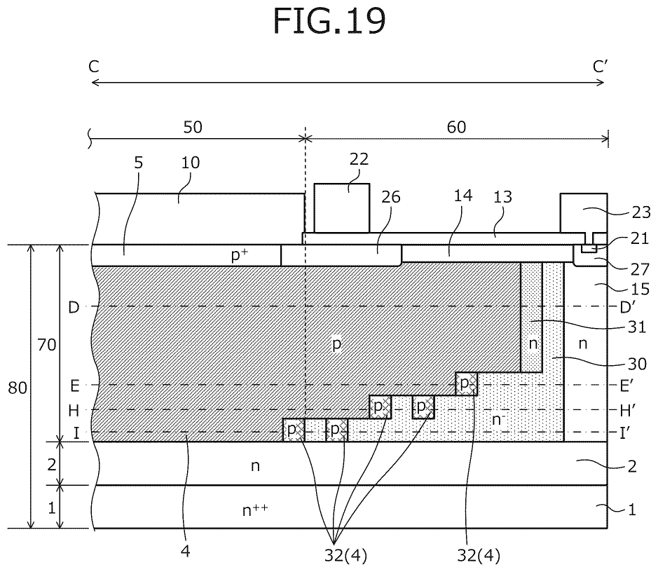

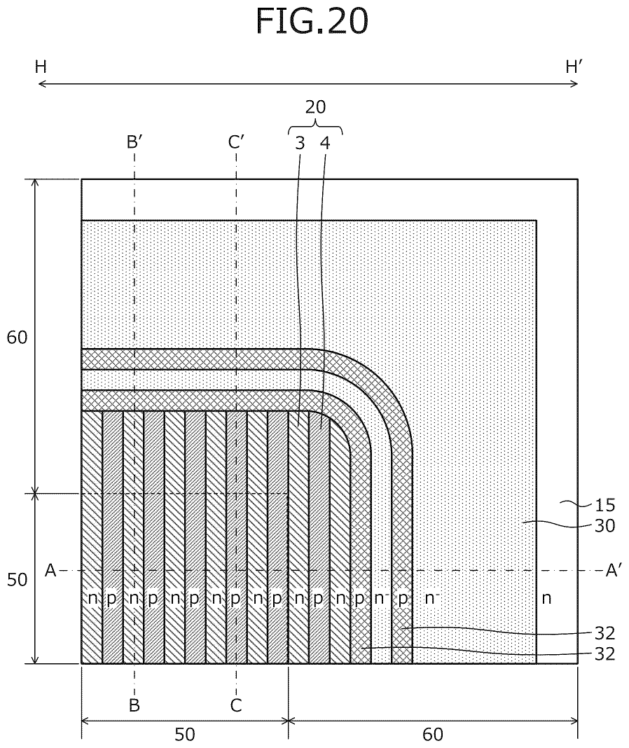

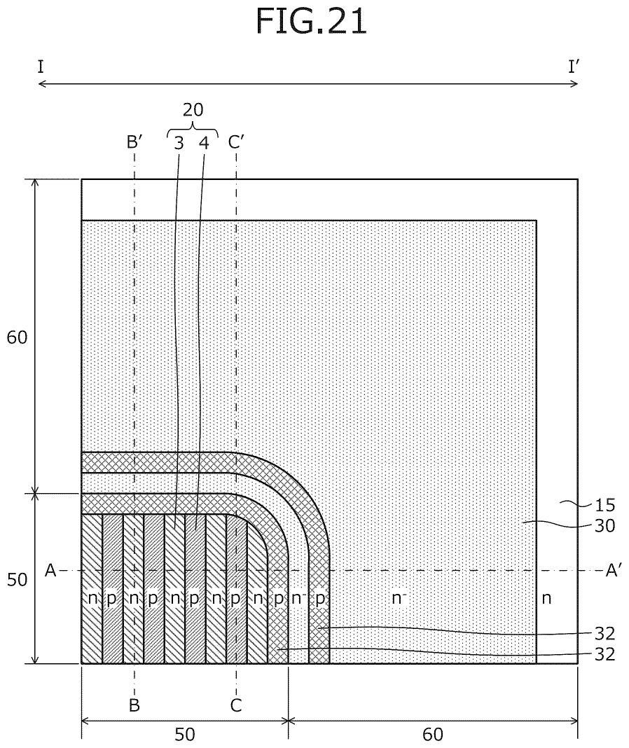

FIGS. 17, 18, 19, 20, and 21 are diagrams depicting a fourth structure of the SJ-MOSFET according to the embodiment. FIG. 17 is a cross-sectional view depicting the fourth structure of the SJ-MOSFET according to the embodiment, along cutting line A-A′. FIG. 18 is a cross-sectional view depicting the fourth structure of the SJ-MOSFET according to the embodiment, along cutting line B-B′. FIG. 19 is a cross-sectional view depicting the fourth structure of the SJ-MOSFET according to the embodiment, along cutting line C-C′. FIG. 20 is a cross-sectional view depicting the fourth structure of the SJ-MOSFET according to the embodiment, along cutting line H-H′. FIG. 21 is a cross-sectional view depicting the fourth structure of the SJ-MOSFET according to the embodiment, along cutting line I-I′. In the fourth structure, plan views along cutting lines D-D′, E-E′, H-H′, I-I′ depicted in FIGS. 19 to 21 correspond to the plan views in FIGS. 2, 3, 17, and 18. Cross-sectional views in FIGS. 19 to 21 depict cross-sectional views along cutting lines A-A′, B-B′, C-C′ in the plan views in FIGS. 1, 2, 17, and 18.

In the third structure depicted in FIGS. 14 to 16, in each location where the n-type column regions 3 become shallower stepwise, one of the p-type annular regions 32 is provided in innermost bottom portions of the p-type column regions 4, closest to the active region 50 (inner side of the location); however, in the fourth structure in FIGS. 17 to 21, in each location where the n-type column regions 3 become shallower stepwise, one of the p-type annular regions 32 is further selectively provided at an outer side of the location and, for example, is further provided in the lower portions of the p-type column regions 4 between the n-type column regions 3 having a same depth. Thus, in the third structure depicted in FIGS. 14 to 16, while the p-type annular regions 32 are provided at three locations, in the fourth structure depicted in FIGS. 17 to 21, the p-type annular regions 32 are provided at five locations. The locations where the p-type annular regions 32 are provided are not limited to the mentioned locations and the p-type annular regions 32 may be further provided at other locations. In the fourth structure having relatively more of the p-type annular regions 32, the hole current may be further distributed as compared to in the first structure, the second structure, and the third structure and a difference in the breakdown voltage of the termination portion parallel to the stripe-like shapes of the parallel pn region 20 parallel to the n⁻-type drift layer 70 and the breakdown voltage of the termination portion orthogonal to the stripe-like shapes of the parallel pn region 20 may be further reduced.

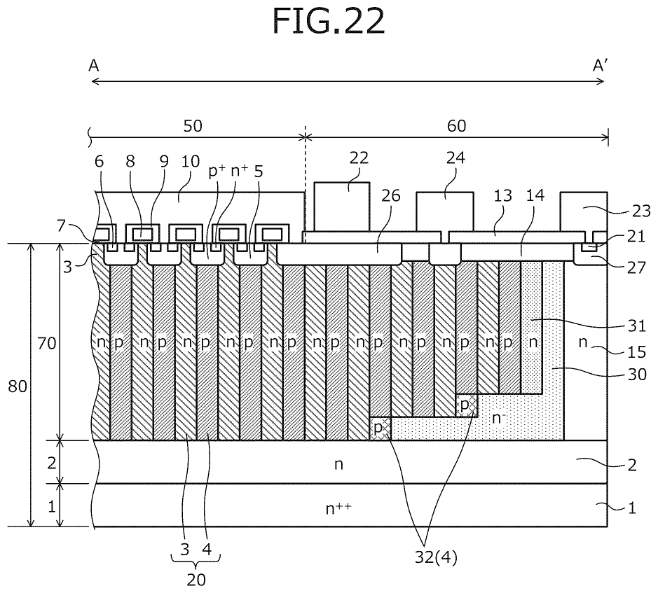

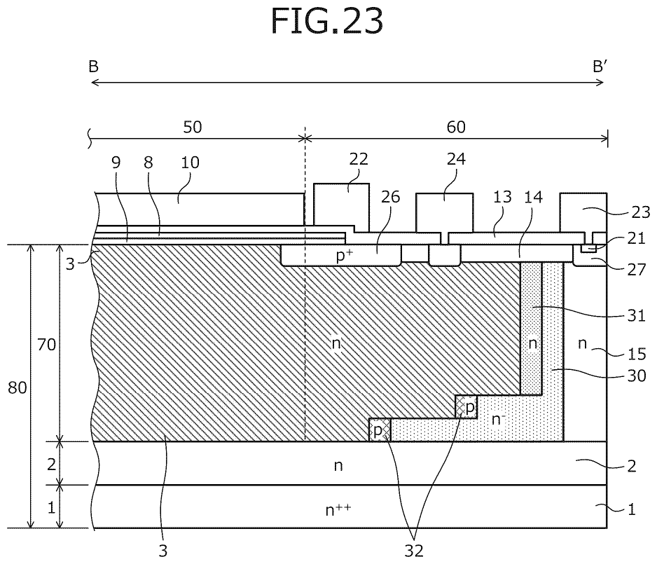

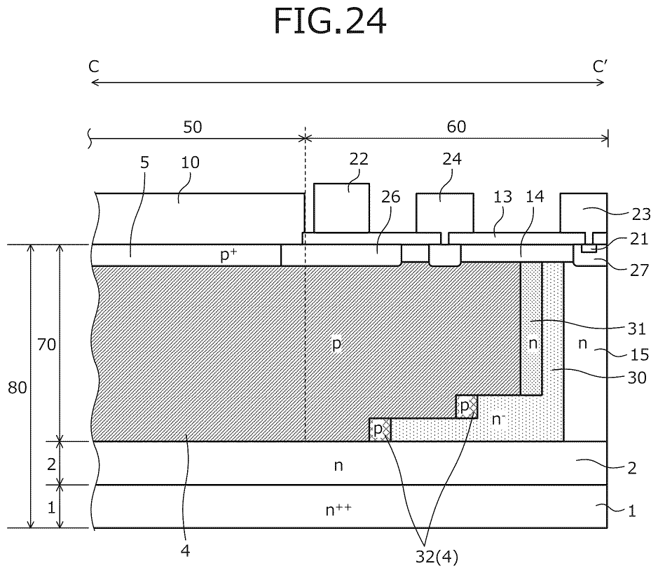

FIG. 22 is a cross-sectional view depicting a fifth structure of the SJ-MOSFET according to the embodiment, along cutting line A-A′. FIG. 23 is a cross-sectional view depicting the fifth structure of the SJ-MOSFET according to the embodiment, along cutting line B-B′. FIG. 24 is a cross-sectional view depicting the fifth structure of the SJ-MOSFET according to the embodiment, along cutting line C-C′. Plan views of the fifth structure are omitted. The cross-sectional views depicted in FIGS. 22 to 24 depict the structure along cutting lines A-A′, B-B′, and C-C′ at positions depicted in the cross-sectional views in FIGS. 2 to 4, respectively.

The fifth structure is a structure in which, in the first structure, a field plate 24 is added in the termination region 60. The field plate 24, via a contact hole provided in the oxide film 13, is electrically connected to the p⁺-type well region 26 provided at surfaces of the n-type column regions 3. The field plate 24 may be added not only to the first structure, but may be further added to the second structure, the third structure, and the fourth structure.

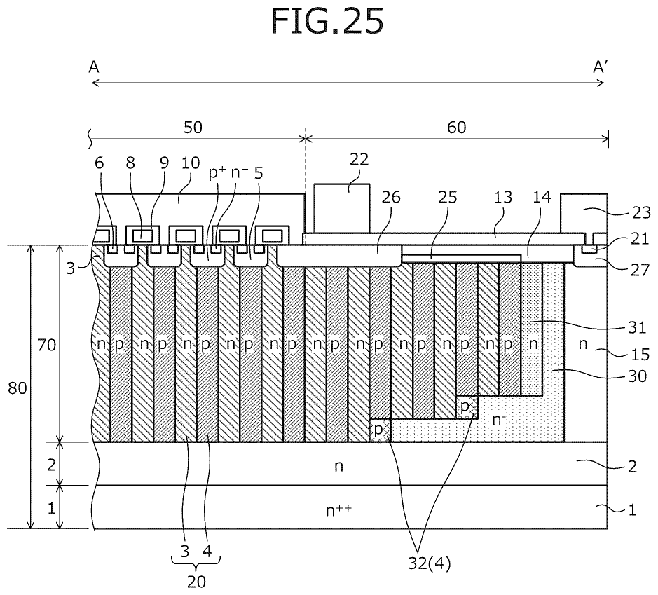

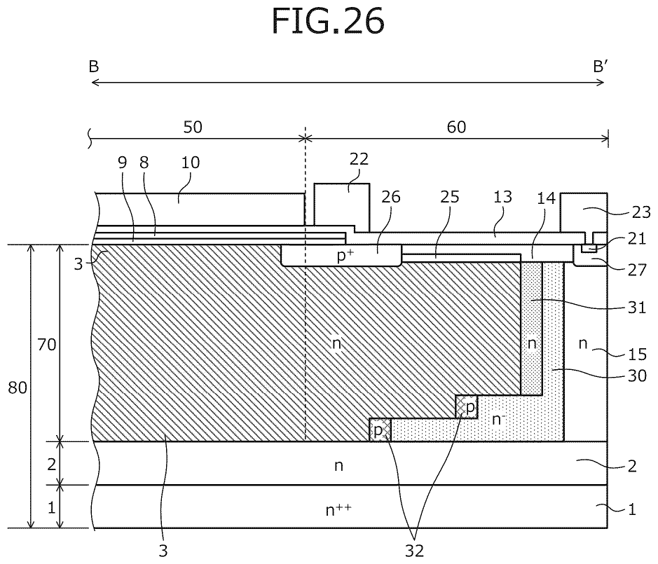

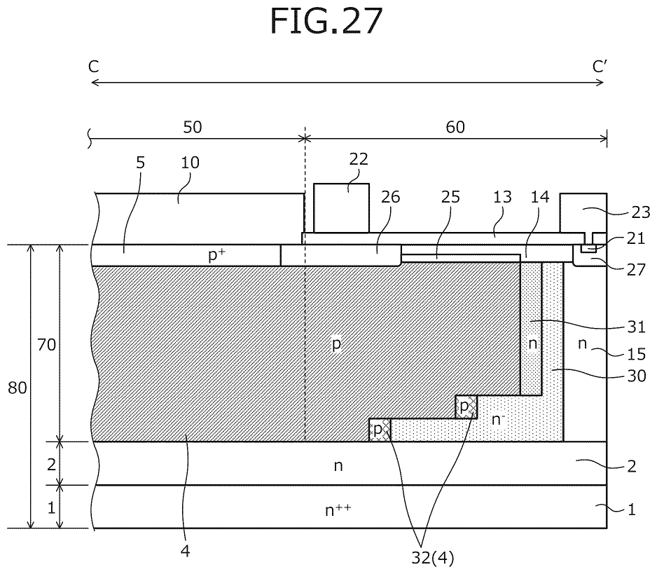

FIG. 25 is a cross-sectional view depicting a sixth structure of the SJ-MOSFET according to the embodiment, along cutting line A-A′. FIG. 26 is a cross-sectional view depicting the sixth structure of the SJ-MOSFET according to the embodiment, along cutting line B-B′. FIG. 27 is a cross-sectional view depicting the sixth structure of the SJ-MOSFET according to the embodiment, along cutting line C-C′. Plan views of the sixth structure are omitted. The cross-sectional views depicted in FIGS. 25 to 27 depict the structure along cutting lines A-A′, B-B′, and C-C′ at positions depicted in the cross-sectional views in FIGS. 2 to 4, respectively.

The sixth structure is a structure in which, in the first structure, a RESURF structure 25 is added in the termination region 60. The RESURF structure 25 is in contact with the p⁺-type well region 26, at an outer side of the p⁺-type well region 26 and is an annular shaped p-type region provided at the surface of the parallel pn region 20. The RESURF structure 25 may be added not only to the first structure, but may be further added to the second structure, the third structure, and the fourth structure.

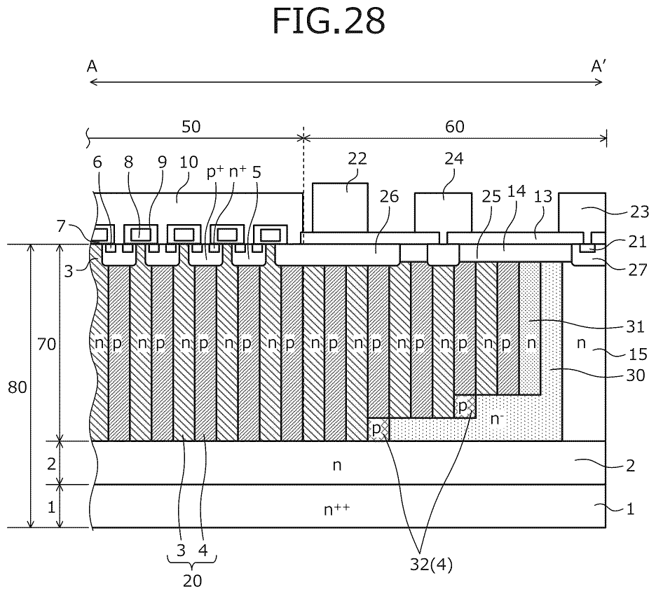

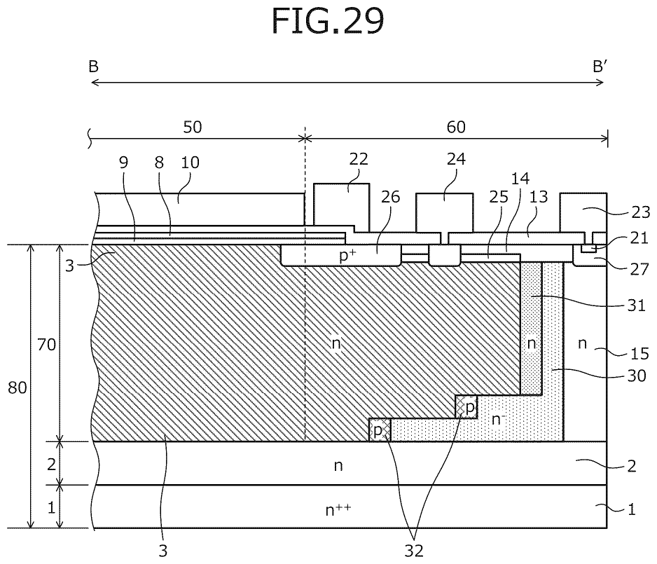

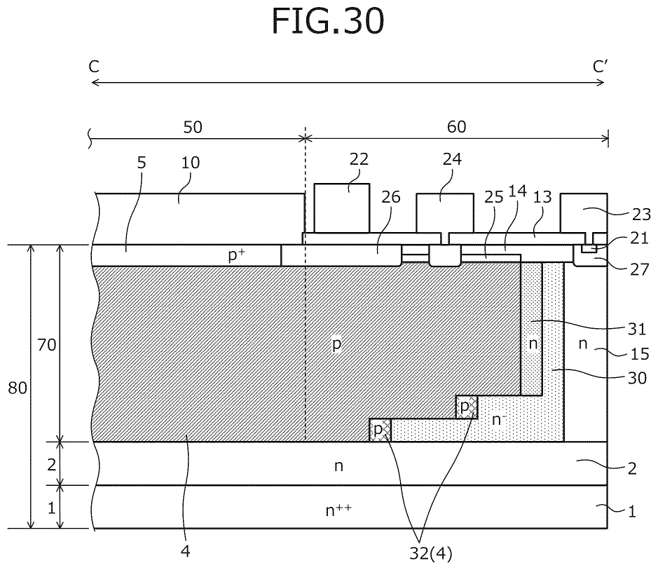

FIG. 28 is a cross-sectional view depicting a seventh structure of the SJ-MOSFET according to the embodiment, along cutting line A-A′. FIG. 29 is a cross-sectional view depicting the seventh structure of the SJ-MOSFET according to the embodiment, along cutting line B-B′. FIG. 30 is a cross-sectional view depicting the seventh structure of the SJ-MOSFET according to the embodiment, along cutting line C-C. Plan views of the seventh structure are omitted. The cross-sectional views depicted in FIGS. 28 to 30 depict the structure along cutting lines A-A′, B-B′, and C-C′ at positions depicted in the cross-sectional views in FIGS. 2 to 4, respectively.

The seventh structure is a structure in which, in the first structure, the field plate 24 and the RESURF structure 25 are added in the termination region 60. The field plate 24 is a same as that of the fifth structure and the RESURF structure 25 is a same as that of the sixth structure. The field plate 24 and the RESURF structure 25 may be added not only to the first structure, but may be further added to the second structure, the third structure, and the fourth structure.

Further, in fabricating the superjunction semiconductor device according to the embodiment, for example, when the p-type column regions 4 of the termination region 60 are formed in the n⁻-type drift layer 70 by ion implantation, the mask is changed, the p-type annular regions 32 are formed, and the n-type annular region 31 is formed at the surface of the n⁻-type drift layer 70 by ion implantation. Another structure may be fabricated similar to an instance in which a MOSFET of, for example, a 1200V breakdown voltage class is fabricated.

As described above, according to the embodiment, a portion of the parallel pn region is connected to parallel columns of the same conductivity type, whereby the manner in which the depletion layer spreads and the electric field distribution of the differing termination structures are made uniform, enabling a difference in the breakdown voltages of the differing structures to be reduced. Furthermore, connection of the parallel columns of the same conductivity type spreads (distributes) current paths for excess carriers discharged during avalanche breakdown and reverse recovery, whereby current may be suppressed from concentrating.

In the foregoing, in the present disclosure, while an instance in which a MOS gate structure formed in a silicon substrate, at a first main surface thereof, is described as an example, without limitation hereto, various modifications are possible such as in the type of semiconductor (for example, silicon carbide (SiC) or the like), surface orientation of the substrate main surface, and the like. Further, in the embodiments of the present disclosure, while a planar-type MOSFET is described as an example, without limitation hereto, application is possible to semiconductor devices of various configurations such as MOS-type semiconductor devices like trench-type MOSFETs, trench-type IGBTs, etc. Further, in the present disclosure, in the embodiments, while the first conductivity type is assumed to be an n-type and the second conductivity type is assumed to be a p-type, the present disclosure is similarly implemented when the first conductivity type is a p-type and the second conductivity type is an n-type.

According to the disclosure described above, a portion of the parallel pn region is connected to parallel columns of the same conductivity type, whereby the manner in which the depletion layer spreads and the electric field distribution of the differing termination structures are made uniform, enabling a difference in the breakdown voltages of the differing structures to be reduced. Furthermore, connection of the parallel columns of the same conductivity type spreads (distributes) current paths for excess carriers discharged during avalanche breakdown and reverse recovery, whereby current may be suppressed from concentrating.

The superjunction semiconductor device according to the present disclosure achieves an effect in that a difference in the breakdown voltages of the differing termination region structures may be reduced.

As described, the superjunction semiconductor device according to the present disclosure is useful for high-voltage semiconductor devices used in power converting equipment, power converting devices of various types of industrial machines, etc.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device, having
an active region through which a current flows, and
a termination structure region surrounding a periphery of the active region in a plan view of the semiconductor device,
the semiconductor device comprising:
a semiconductor substrate of a first conductivity type;
a first semiconductor layer of the first conductivity type, provided at a surface of the semiconductor substrate, the first semiconductor layer having a dopant concentration lower than a dopant concentration of the semiconductor substrate;
a second semiconductor layer of the first conductivity type, provided at a surface of the first semiconductor layer, the second semiconductor layer having a dopant concentration lower than the dopant concentration of the first semiconductor layer; and
a parallel pn region provided in the second semiconductor layer, the parallel pn region including a plurality of first column regions of the first conductivity type and a plurality of second column regions of a second conductivity type that are disposed in parallel and repeatedly alternating with each other in a first direction parallel to the surface of the second semiconductor layer, each of the plurality of first and second column regions extending to a depth in a depth direction perpendicular to the first direction, wherein
in the termination structure region, the depths of the plurality of first and second column regions decrease stepwise in the first direction, to form a plurality of height steps from an inner side of the parallel pn region to an outer side thereof, and
in a sectional view of the semiconductor device parallel to the surface of the second semiconductor layer, the parallel pn region is surrounded by a semiconductor region of an annular shape, which has a constant distance from the active region and is connected to either the first column regions or the second column regions that are of a same conductivity type as the semiconductor region.

2. The semiconductor device according to claim 1, wherein said semiconductor region is a first semiconductor region of the first conductivity type, and is connected to the plurality of first column regions.

3. The semiconductor device according to claim 1, wherein said semiconductor region is a second semiconductor region of the second conductivity type, and is connected to the plurality of second column regions.

4. The semiconductor device according to claim 3, wherein the semiconductor device includes a plurality of the second semiconductor regions, each directly contacting one of the plurality of height steps in the first direction, and encircling said one height step in the plan view.

5. The semiconductor device according to claim 3, wherein the semiconductor device includes a plurality of the second semiconductor regions, each below one of the plurality of second column regions, intervening between adjacent two of the plurality of first column regions, and having a thickness in the depth direction that equals to a difference in depth between two adjacent steps of the plurality of height steps.

6. The semiconductor device according to claim 1, wherein
the depths of the plurality of first and second column regions are shallower in the termination structure region than in the active region.

7. The semiconductor device according to claim 1, wherein the plurality of height steps includes three or more steps.
